(19) United States
(12) Patent Application Publication
(10) Pub. No.: US 2024/0170470 A1
(43) Pub. Date: May 23, 2024

(54) DISPLAY APPARATUS

(71) Applicant: Samsung Display Co., Ltd., Yongin-si (KR)

(72) Inventors: Donghan Kang, Yongin-si (KR); Jeehoon Kim, Yongin-si (KR); Sunggwon Moon, Yongin-si (KR); Seungsok Son, Yongin-si (KR); Shinhyuk Yang, Yongin-si (KR); Woogeun Lee, Yongin-si (KR)

(73) Assignee: Samsung Display Co., Ltd., Yongin-si (KR)

(21) Appl. No.: 18/513,697

(22) Filed: Nov. 20, 2023

(30) Foreign Application Priority Data
Nov. 23, 2022 (KR) 10-2022-0158531

(51) Int. Cl. H01L 25/16; H01L 25/075; H01L 33/62

(52) U.S. Cl. CPC H01L 25/167; H01L 25/0753; H01L 33/62

(57) ABSTRACT

A display apparatus includes a transistor, a light-emitting diode including a first electrode electrically connected to the transistor, a second electrode, and an intermediate layer between the first and second electrodes, a bus line adjacent to the light-emitting diode, a first insulating layer on the bus line, a second insulating layer on the first insulating layer, a conductive layer electrically connected to the bus line through a first opening in the first insulating layer and a second opening in the second insulating layer, a third insulating layer on the second insulating layer and including a third opening overlapping the first opening and the second opening, and a fourth insulating layer on the third insulating layer and including a fourth opening overlapping the conductive layer, wherein a portion of the second electrode of the light-emitting diode is in contact with the conductive layer through the third opening and the fourth opening.

### CROSS-REFERENCE TO RELATED APPLICATION

This application is based on and claims priority to and benefits of Korean Patent Application No. 10-2022-0158531 under 35 U.S.C. § 119, filed on Nov. 23, 2022, in the Korean Intellectual Property Office (KIPO), the disclosure of which is incorporated by reference herein in its entirety.

### BACKGROUND

### 1. Technical Field

One or more embodiments relate to a display apparatus.

### 2. Description of the Related Art

Generally, in a display apparatus such as an organic light-emitting display apparatus, transistors are arranged in a display area to control the luminance of a light-emitting diode and the like. The transistors are configured to control the corresponding light-emitting diode to emit light having a certain color by using a transferred data signal, a driving voltage, and a common voltage.

One of the electrodes of the light-emitting diode (e.g., an anode) may receive a certain voltage through a transistor, and the other electrode (e.g., a cathode) may receive a voltage through a bus line.

### SUMMARY

One or more embodiments include a display apparatus in which a voltage drop of a light-emitting diode may be prevented to provide a high-quality image. However, such a technical problem is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display apparatus includes a transistor, a light-emitting diode including a first electrode electrically connected to the transistor, a second electrode on the first electrode, and an intermediate layer between the first electrode and the second electrode, a bus line adjacent to the light-emitting diode, a first insulating layer arranged on the bus line, a second insulating layer arranged on the first insulating layer, a conductive layer electrically connected to the bus line through a first opening defined in the first insulating layer and a second opening defined in the second insulating layer, a third insulating layer arranged on the second insulating layer and including a third opening overlapping the first opening and the second opening in a plan view, and a fourth insulating layer arranged on the third insulating layer and including a fourth opening overlapping the conductive layer in a plan view, wherein a portion of the second electrode of the light-emitting diode is in contact with the conductive layer through the third opening and the fourth opening.

The conductive layer may be in contact with an entire top surface of the bus line which is exposed through the first opening of the first insulating layer.

An edge portion of the conductive layer may be in direct contact with a side surface of the first insulating layer defining the first opening.

A portion of the third insulating layer surrounding the third opening may include an overhang structure protruding toward the third opening from an edge where top and side surfaces of the second insulating layer meet each other.

The display apparatus may further include a dummy conductive layer located on the overhang structure of the third insulating layer and separated from the conductive layer. The dummy conductive layer and the conductive layer may include a same material.

A portion of the fourth insulating layer may overlap a portion of the overhang structure of the third insulating layer in a plan view and may have a forward-tapered inclined surface with respect to a top surface of the conductive layer.

The intermediate layer may include a first portion arranged on the forward-tapered inclined surface of the fourth insulating layer and the top surface of the conductive layer, and a second portion separated from the first portion and located over the overhang structure, wherein the portion of the second electrode of the light-emitting diode may be in direct contact with the conductive layer beyond an edge of the first portion of the intermediate layer.

The conductive layer and the first electrode of the light-emitting diode may include the same material.

The transistor may include a semiconductor layer, a gate electrode overlapping a channel region of the semiconductor layer in a plan view, and an electrode electrically connected to one selected from among regions arranged on sides of the channel region of the semiconductor layer, and the bus line and the gate electrode or the electrode may include the same material.

The first insulating layer and the second insulating layer may include inorganic insulating materials different from each other.

An inclination angle of a side surface of the first insulating layer defining the first opening may be different from an inclination angle of a side surface of the second insulating layer defining the second opening.

According to one or more embodiments, a display apparatus includes a display area and a non-display area outside the display area, a bus line arranged in the display area, a multi-insulating layer including a first insulating layer and a second insulating layer and having an opening overlapping the bus line in a plan view, a conductive layer in direct contact with the bus line through the opening of the multi-insulating layer, a third insulating layer arranged on the multi-insulating layer and including an overhang structure protruding from an edge where top and side surfaces of the multi-insulating layer meet each other, a fourth insulating layer arranged on the third insulating layer, and a light-emitting diode arranged in the display area and including a first electrode, a second electrode on the first electrode, and an intermediate layer between the first electrode and the second electrode, wherein the second electrode of the light-emitting diode is electrically connected to the conductive layer through an opening of the third insulating layer and an opening of the fourth insulating layer each overlapping the opening of the multi-insulating layer in a plan view.

An edge of the conductive layer may be on the side surface of the multi-insulating layer.

Each of the first insulating layer and the second insulating layer may include an inorganic insulating material.

The inorganic insulating material of the first insulating layer may be different from the inorganic insulating material of the second insulating layer.

The display apparatus may further include a dummy conductive layer located on the overhang structure of the third insulating layer and separated from the conductive layer. The dummy conductive layer and the conductive layer may include a same material.

A portion of the fourth insulating layer may overlap a portion of the overhang structure of the third insulating layer in a plan view and may have a forward-tapered inclined surface with respect to a top surface of the conductive layer.

The intermediate layer may include a first portion arranged on the forward-tapered inclined surface of the fourth insulating layer and the top surface of the conductive layer, and a second portion separated from the first portion and located over the overhang structure, wherein a portion of the second electrode of the light-emitting diode may be in direct contact with the conductive layer beyond an edge of the first portion of the intermediate layer.

The conductive layer and the first electrode of the light-emitting diode may include a same material.

The display apparatus may further include a transistor arranged in the display area and electrically connected to the first electrode of the light-emitting diode, wherein the transistor may include a semiconductor layer, a gate electrode overlapping a channel region of the semiconductor layer in a plan view, and an electrode electrically connected to one region selected from among regions arranged on sides of the channel region of the transistor. The bus line and the gate electrode or the electrode may include a same material.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic plan view of a display panel of the display apparatus of FIG. 1;

FIG. 3 is a schematic plan view illustrating a portion of a display area of a display panel according to an embodiment;

FIG. 4 is a schematic cross-sectional view of a portion of a display panel according to an embodiment, taken along lines A-A′ and B-B′ of FIG. 3 and line C-C′ of FIG. 2;

FIGS. 5A and 5B are schematic cross-sectional views illustrating a stacked structure of a light-emitting diode according to an embodiment;

FIG. 6A is a schematic enlarged cross-sectional view of region IV of FIG. 4;

FIGS. 6B to 6D are schematic views each illustrating a modified embodiment of FIG. 6A;

FIG. 7 is a schematic plan view of a structure along line B-B′ shown in FIG. 4;

FIG. 8 is a schematic cross-sectional view illustrating a structure on a bus line of a display panel according to another embodiment;

FIGS. 9 to 15 are schematic cross-sectional views of a process of manufacturing a display panel according to an embodiment;

FIGS. 16 to 18 are schematic cross-sectional views illustrating part of a process of manufacturing a display panel according to another embodiment and may correspond to modified embodiments of FIGS. 10 to 12, respectively; and

FIG. 19 is a schematic cross-sectional view illustrating a display area of a display panel according to another embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As the description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

One or more embodiments will be described below in more detail with reference to the accompanying drawings. Those elements that are the same or are in correspondence with each other are rendered the same reference numeral and/or reference characters regardless of the figure number, and redundant descriptions thereof are omitted.

While such terms as “first” and “second” may be used to describe various elements, such elements must not be limited to the above terms. The above terms are used only to distinguish one element from another.

The singular forms, such as “a” and “an,” as used herein are intended to include the plural forms (or plural meanings) as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a certain process order may be performed differently from the described order. For example, two consecutively described processes may be performed substantially at the same time or performed in an order opposite to the described order.

The term “and/or” includes all combinations of one or more of which associated configurations may define. For example. “A and/or B” may be understood to mean “A, B, or A and B.”

For the purposes of this disclosure, the phrase “at least one of A and B” may be construed as A only. B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an element is referred to as being “on,” “connected to,” or “coupled to” another element, it may be directly on, connected to, or coupled to the other element or intervening elements or layers may be present. When, however, an element is referred to as being “directly on.” “directly connected to.” or “directly coupled to” another element, there are no intervening elements or layers present. To this end, the term “connected” may refer to physical, electrical, and/or fluid connection, with or without intervening elements.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

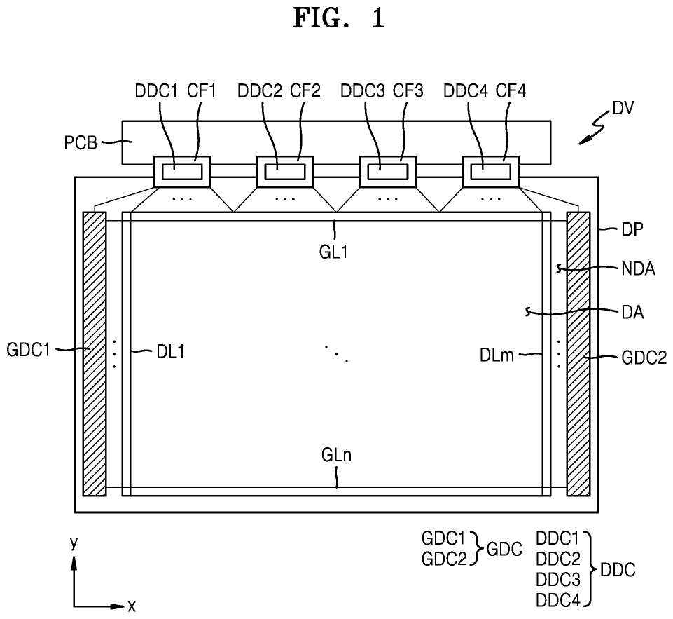

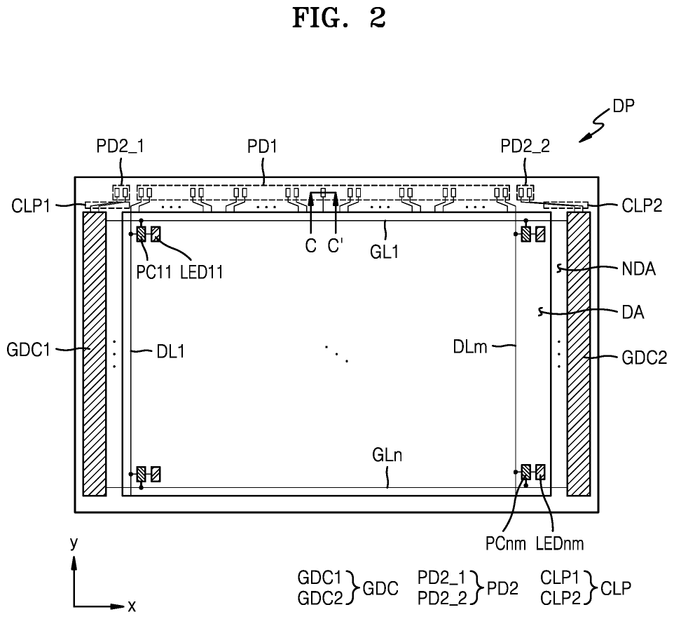

FIG. 1 is a schematic plan view of a display apparatus DV according to an embodiment. FIG. 2 is a schematic plan view of a display panel DP of the display apparatus DV of FIG. 1.

Referring to FIGS. 1 and 2, the display apparatus DV may include the display panel DP for displaying an image and a driver for driving the display panel DP. As an example, the driver may include a gate driver GDC and a data driver DDC.

The display panel DP may include a display area DA displaying an image and a non-display area NDA adjacent to the display area DA. The display area DA may be an area where an image is displayed, and the non-display area NDA may be a bezel area where an image is not displayed. Although FIGS. 1 and 2 illustrate a structure in which the non-display area NDA entirely surrounds the display area DA, one or more embodiments are not limited thereto. The non-display area NDA may partially surround the display area DA. For example, the non-display area NDA may be arranged on only a side of the display area DA.

The display panel DP may include gate lines GL1 to GLn, data lines DL1 to DLm, and sub-pixel circuits PC11 to PCnm, and light-emitting diodes LED11 to LEDnm electrically connected thereto. The gate lines GL1 to GLn may each extend in a first direction (e.g., a direction x) and may be parallel to each other in a second direction (e.g., a direction y) crossing the first direction (e.g., the direction x). The data lines DL1 to DLm may be parallel to each other in the first direction (e.g., the direction x) and may each extend in the second direction (e.g., the direction y).

The sub-pixel circuits PC11 to PCnm may be arranged in the first direction (e.g., the direction x) and the second direction (e.g., the direction y) in the display area DA. As an example, the sub-pixel circuits PC11 to PCnm may be arranged in a matrix form. The sub-pixel circuits PC11 to PCnm may each be electrically connected to at least one of the gate lines GL1 to GLn and at least one of the data lines DL1 to DLm. The light-emitting diodes LED11 to LEDnm may be respectively electrically connected to the sub-pixel circuits PC11 to PCnm.

The gate driver GDC may sequentially output gate signals to the gate lines GL1 to GLn. In an embodiment, the gate driver GDC may include a first gate driver GDC1 and a second gate driver GDC2. The first gate driver GDC1 may be electrically connected to an end of the gate lines GL1 to GLn, and the second gate driver GDC2 may be electrically connected to another end of the gate lines GL1 to GLn. Each of the first and second gate drivers GDC1 and GDC2 may include a shift register for sequentially outputting gate signals. The first and second gate drivers GDC1 and GDC2 may operate simultaneously to output gate signals to a same gate line simultaneously. Accordingly, each of the gate lines GL1 to GLn may receive gate signals from the first and second gate drivers GDC1 and GDC2 through both end portions thereof.

Although FIGS. 1 and 2 illustrate a structure in which two gate drivers, e.g., first and second gate drivers GDC1 and GDC2 are electrically connected to both ends of the gate lines GL1 to GLn, respectively, one or more embodiments are not limited thereto. For example, only one of the first and second gate drivers GDC1 and GDC2 may be electrically connected to the gate lines GL1 to GLn.

The first and second gate drivers GDC1 and GDC2 may be embedded in the display panel DP. For example, the first and second gate drivers GDC1 and GDC2 may be formed in the non-display area NDA of the display panel DP during a process of forming the sub-pixel circuits PC11 to PCnm in the display area DA of the display panel DP.

The data driver DDC may convert image signals into data voltages and may apply the data voltages to the data lines DL1 to DLm of the display panel DP. The data driver DDC may include data driving chips DDC1 to DDC4. Each of the data driving chips DDC1 to DDC4 may be electrically connected to corresponding data lines among the data lines DL1 to DLm. Although FIG. 1 illustrates four data driving chips DDC1 to DDC4, the number of data driving chips DDC1 to DDC4 may be variously changed.

The display apparatus DV may include first to fourth flexible films CF1 to CF4 and a printed circuit board PCB. The first to fourth flexible films CF1 to CF4 may be between the display panel DP and the printed circuit board PCB and may electrically connect the display panel DP and the printed circuit board PCB to each other. An end portion of each of the first to fourth flexible films CF1 to CF4 may be electrically connected to the display panel DP, and another end portion thereof may be electrically connected to the printed circuit board PCB.

Although FIG. 1 illustrates a structure in which the data driving chips DDC1 to DDC4 are mounted on the first to fourth flexible films CF1 to CF4, respectively, one or more embodiments are not limited thereto. For example, the data driving chips DDC1 to DDC4 may be directly mounted on the display panel DP in a Chip-On-Glass (COG) manner.

Various circuits for generating various control signals and power signals required to drive the display panel DP and the panel driver may be provided on the printed circuit board PCB.

The display panel DP may further include a first pad portion PD1 and a second pad portion PD2. The first and second pad portions PD1 and PD2 may be arranged in the non-display area NDA. The first pad portion PD1 may include pads (e.g., data pads) electrically connected to the data lines DL1 to DLm. The first pad portion PD1 may be coupled to the first to fourth flexible films CF1 to CF4 to receive data voltages from the data driving chips DDC1 to DDC4 respectively mounted on the first to fourth flexible films CF1 to CF4.

The second pad portion PD2 may include a first driving pad portion PD2_1 electrically connected to the first gate driver GDC1 and a second driving pad portion PD2_2 electrically connected to the second gate driver GDC2. The first driving pad portion PD2_1 may include pads (e.g., first driving pads) for providing a first gate driving signal to the first gate driver GDC1, and the second driving pad portion PD2_2 may include pads (e.g., second driving pads) for providing a second gate driving signal to the second gate driver GDC2.

The second pad portion PD2 may be electrically connected to some of the first to fourth flexible films CF1 to CF4. As an example, the first driving pad portion PD2_1 may be electrically connected to the first flexible film CF1 among the first to fourth flexible films CF1 to CF4, and the second driving pad portion PD2_2 may be electrically connected to the fourth flexible film CF4 among the first to fourth flexible films CF1 to CF4. The first gate driving signal may be a signal output from the first data driving chip DDC1 mounted on the first flexible film CF1 or a signal supplied from the printed circuit board PCB. The second gate driving signal may be a signal output from the fourth data driving chip DDC4 mounted on the fourth flexible film CF4 or a signal supplied from the printed circuit board PCB.

The display panel DP may further include an intermediate wiring portion CLP electrically connecting the second pad portion PD2 to the gate driver GDC. In an embodiment, the intermediate wiring portion CLP may include a first intermediate wiring portion CLP1 and a second intermediate wiring portion CLP2. The first intermediate wiring portion CLP1 may electrically connect the first driving pad portion PD2_1 to the first gate driver GDC1, and the second intermediate wiring portion CLP2 may electrically connect the second driving pad portion PD2_2 to the second gate driver GDC2.

The display apparatus DV may be used as the display screen of various products, such as a television, a laptop computer, a monitor, a billboard, and an Internet of things (IOT) device. As another example, the display apparatus DV may be used as the display screen of portable electronic devices, such as a mobile phone, a smartphone, a tablet personal computer (PC), a mobile communication terminal, an electronic notebook, an e-book reader, a portable multimedia player (PMP), a navigation system, and an ultra-mobile PC (UMPC). The display apparatus DV according to an embodiment may be used as a car's dashboard, a center information display (CID) placed on a car's center fascia or dashboard, a room mirror display replacing a car's side-view mirror, or a display placed on the back of a front seat of a car as an entertainment device for the car's rear seat. The above-described electronic device may be bendable, foldable, or rollable.

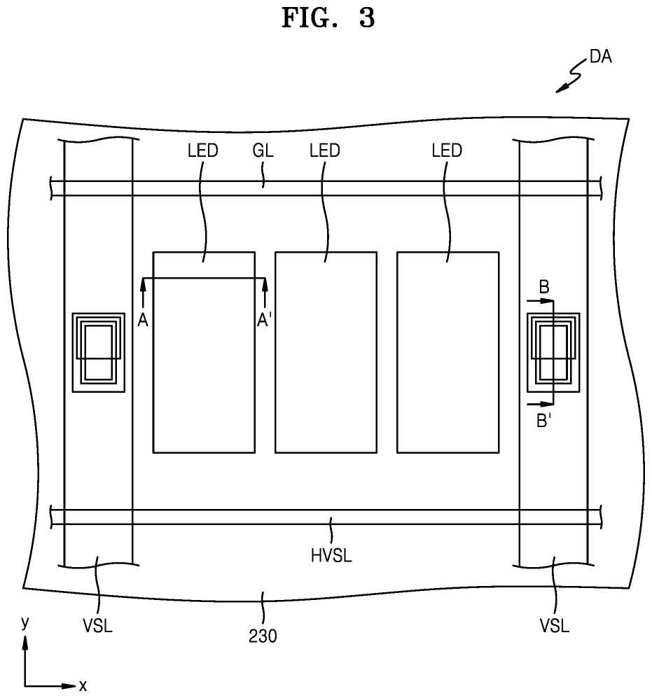

FIG. 3 is a schematic plan view illustrating a portion of the display area DA of a display panel according to an embodiment.

Referring to FIG. 3, light-emitting diodes LED may be arranged in the display area DA, and a bus line VSL may be adjacent to a light-emitting diode LED. As an embodiment, FIG. 3 illustrates three light-emitting diodes LED arranged between two adjacent bus lines VSL, but one or more embodiments are not limited thereto. In another embodiment, the number of light-emitting diodes LED arranged between two adjacent bus lines VSL may be variously changed.

A gate line GL may extend in a first direction (e.g., a direction x) to cross the bus line VSL. A horizontal bus line HVSL extending in the first direction (e.g., the direction x) may be arranged in the display area DA to cross the bus line VSL. The horizontal bus line HVSL may be electrically connected to the bus line VSL in the display area DA. Since the structure shown in FIG. 3 is repeatedly arranged in the display area DA, bus lines VSL and horizontal bus lines HVSL may form a mesh structure in the display area DA.

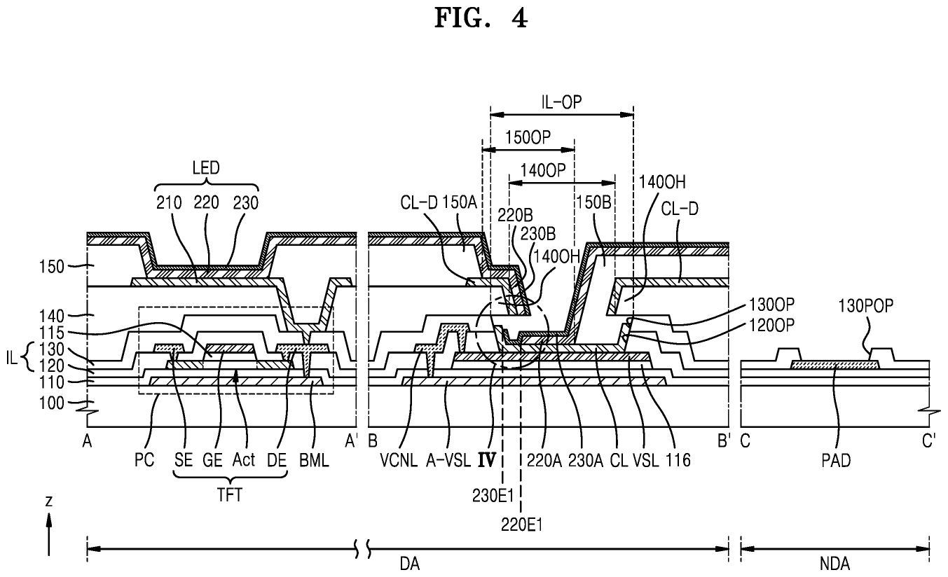

The light-emitting diode LED may include a first electrode (e.g., an anode), a second electrode 230 (e.g., a cathode) above the first electrode, and an intermediate layer between the first electrode and the second electrode 230. The second electrode 230 may have an area enough to entirely cover the display area DA. Through the opening of insulating layers located on the bus line VSL, the second electrode 230 may be electrically connected to the bus line VSL in the display area DA, and a description thereof is given below with reference to FIGS. 4 to 7.

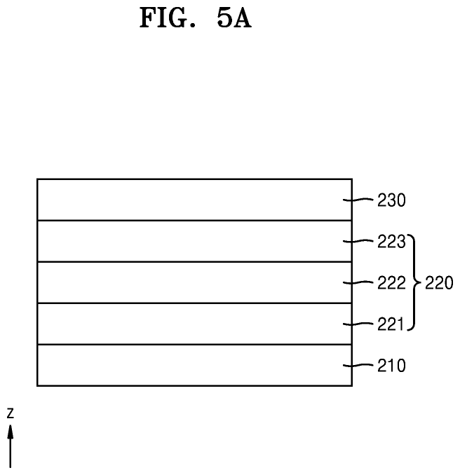

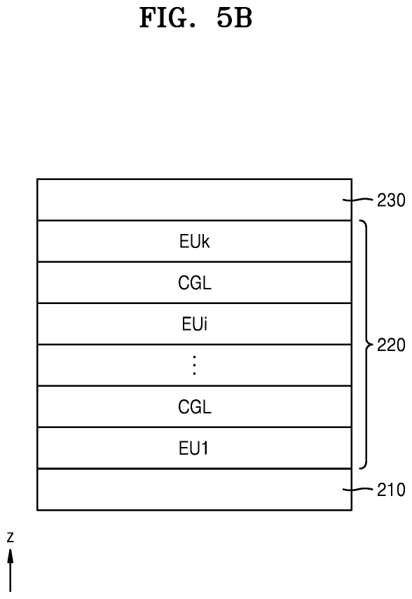

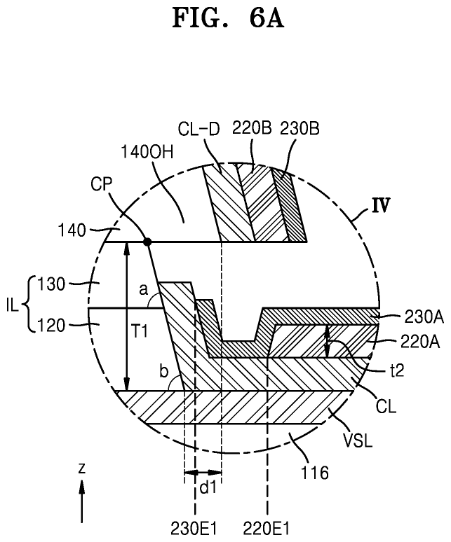

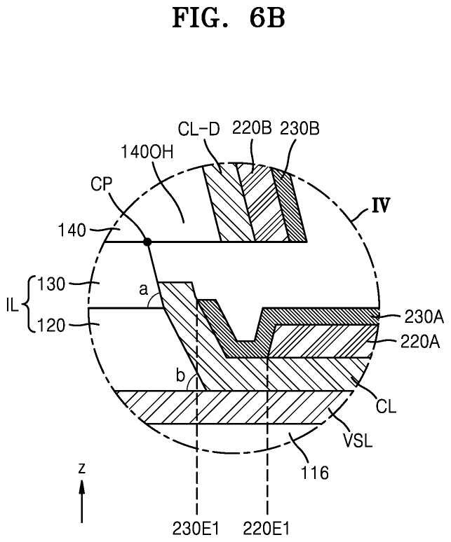

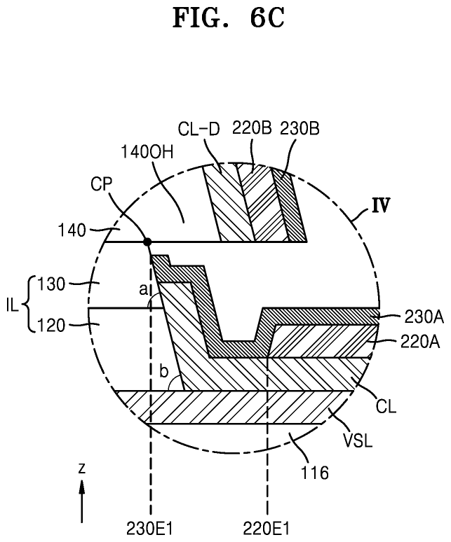

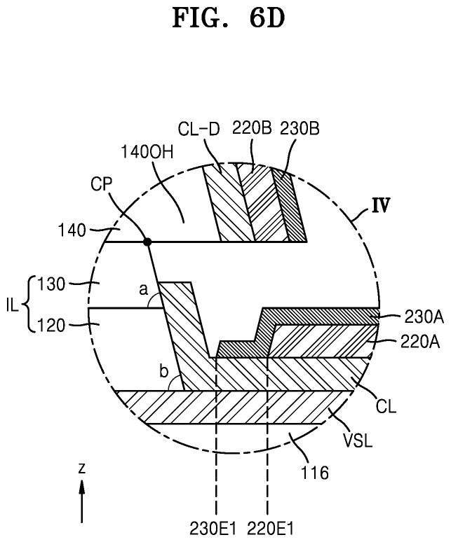

FIG. 4 is a schematic cross-sectional view of a portion of a display panel according to an embodiment, taken along lines A-A′ and B-B′ of FIG. 3 and line C-C′ of FIG. 2. FIGS. 5A and 5B are schematic cross-sectional views illustrating a stacked structure of a light-emitting diode according to an embodiment. FIG. 6A is a schematic enlarged cross-sectional view of region IV of FIG. 4. FIGS. 6B to 6D are schematic view each showing a modified embodiment of FIG. 6A.

Referring to line A-A′ of FIG. 4, a sub-pixel circuit PC may be disposed on a substrate 100, and the light-emitting diode LED may be disposed above (or on) the sub-pixel circuit PC. The sub-pixel circuit PC may include transistors and a storage capacitor, and as an embodiment, FIG. 4 illustrates a transistor TFT among the transistors included in the sub-pixel circuit PC.

The substrate 100 may include a glass material or a resin material. The glass material may include transparent glass including SiO₂ as a main component. The resin material may include, e.g., at least one of polymer resin, such as polyethersulfone, polyacrylate, polyetherimide, polyethylene naphthalate, polyethylene terephthalate, polyphenylene sulfide, polyarylate, polyimide, polycarbonate, cellulose triacetate, cellulose acetate propionate, etc.

A buffer layer 110 may be disposed on the substrate 100. The buffer layer 110 may include an inorganic insulating material, such as silicon oxide, silicon nitride, and/or silicon oxynitride, and may have a single-layer or multi-layer structure including the above-described material.

The transistor TFT may include a semiconductor layer Act on the buffer layer 110 and a gate electrode GE overlapping a channel region of the semiconductor layer Act. Regions respectively arranged on both sides of the channel region of the semiconductor layer Act may be regions doped with impurities or be made conductive, and one of the two regions may be a source region, and the other may be a drain region. The source region may be electrically connected to a source electrode SE, and/or the drain region may be electrically connected to a drain electrode DE.

The semiconductor layer Act may include, e.g., an oxide semiconductor. The oxide semiconductor may include, e.g., at least one of indium gallium zinc oxide (IGZO), zinc tin oxide (ZTO), indium zinc oxide (IZO), etc. In another embodiment, the semiconductor layer Act may include, e.g., polysilicon, amorphous silicon, or an organic semiconductor.

The gate electrode GE may be disposed above the semiconductor layer Act with a gate insulating layer 115 therebetween. The gate electrode GE may include a conductive material including, e.g., at least one of molybdenum (Mo), aluminum (Al), copper (Cu), titanium (Ti), etc., and may have a multi-layer or single-layer structure including the above-described material. In an embodiment, the gate electrode GE may include a multi-layer structure of a titanium layer and a copper layer disposed on the titanium layer, or may include a multi-layer structure of a titanium layer, a copper layer on the titanium layer, and an indium tin oxide (ITO) layer on the copper layer. The gate insulating layer 115 may include an inorganic insulating material, such as silicon oxide, silicon nitride, and/or silicon oxynitride, and may have a single-layer or multi-layer structure including the above-described material.

As an embodiment, FIG. 4 illustrates that the gate insulating layer 115 and the gate electrode GE are patterned together by a same process and thus a top surface of the gate insulating layer 115 entirely overlaps the gate electrode GE, but one or more embodiments are not limited thereto. In another embodiment, the gate insulating layer 115 may entirely overlap a top surface of the substrate 100 as the buffer layer 110, a first insulating layer 120, and/or a second insulating layer 130 do.

The first insulating layer 120 may be disposed on the gate electrode GE. The first insulating layer 120 may include an inorganic insulating material. For example, the first insulating layer 120 may include an inorganic insulating material, such as silicon oxide, silicon nitride, and/or silicon oxynitride, and may have a single-layer or multi-layer structure including the above-described material.

The source electrode SE and/or the drain electrode DE may be disposed on the first insulating layer 120. The source electrode SE and/or the drain electrode DE may include, e.g., one or more materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may include a single-layer or multi-layer structure including the above-described material.

The source electrode SE and/or the drain electrode DE may be electrically connected to a bottom conductive layer BML. The bottom conductive layer BML may include, e.g., one or more materials among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), and copper (Cu). The bottom conductive layer BML may include a metal layer including the above-described metal element, or may include a stacked structure of a metal layer including the above-described metal element and a transparent conductive oxide layer on the metal layer. The bottom conductive layer BML may improve characteristics of the transistor TFT.

The second insulating layer 130 may be disposed on the transistor TFT, for example, on the source electrode SE and/or the drain electrode DE. The second insulating layer 130 may include an inorganic insulating material. The second insulating layer 130 may include, e.g., an inorganic insulating material, such as silicon oxide, silicon nitride, and/or silicon oxynitride, and may have a single-layer or multi-layer structure including the above-described material. The second insulating layer 130 and the first insulating layer 120 may include different inorganic insulating materials. For example, the second insulating layer 130 may include silicon nitride as a barrier for the transistor TFT, and the first insulating layer 120 may include silicon oxynitride in consideration of operation characteristics of the transistor TFT.

A third insulating layer 140 may be disposed on the second insulating layer 130. The third insulating layer 140 and the insulating layers (e.g., a multi-insulating layer IL) disposed under the third insulating layer 140 may include different insulating materials. For example, the third insulating layer 140 may include a material different from inorganic insulating materials of the multi-insulating layer (IL), for example, an organic insulating material. The third insulating layer 140 may include an organic insulating material, such as acryl, benzocyclobutene (BCB), polyimide, and/or hexamethyldisiloxane (HMDSO).

A first electrode 210 of the light-emitting diode LED may be disposed on the third insulating layer 140. The first electrode 210 may be electrically connected to the transistor TFT through a contact hole in the third insulating layer 140. FIG. 4 illustrates the first electrode 210 directly electrically connected to the transistor TFT, but one or more embodiments are not limited thereto. In another embodiment, a conductor may be further disposed between the first electrode 210 and the transistor TFT, and the first electrode 210 and the transistor TFT may be electrically connected to each other through the conductor.

The first electrode 210 may include transparent conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 210 may include a reflective layer including, e.g., silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 210 may further include a layer that is provided on/under the above-described reflective layer and formed of ITO, IZO, ZnO, or In₂O₃. For example, the first electrode 210 may have a three-layer structure in which an ITO layer, a silver (Ag) layer, and an ITO layer are stacked each other.

A fourth insulating layer 150 may cover the edge of the first electrode 210. The fourth insulating layer 150 may include a light-emitting opening located at a central portion of the first electrode 210. An area (or a width) of the light-emitting opening of the fourth insulating layer 150 may correspond to an area (or a width) of an emission area of the light-emitting diode LED. The fourth insulating layer 150 may include an organic insulating material. For example, the fourth insulating layer 150 may include an organic insulating material, such as acryl, benzocyclobutene (BCB), polyimide, and/or hexamethyldisiloxane (HMDSO).

An intermediate layer 220 may be disposed on the fourth insulating layer 150 and may contact the first electrode 210 through the light-emitting opening in the fourth insulating layer 150. The intermediate layer 220 may include a high-molecular weight organic material or low-molecular weight organic material emitting light of a certain color. The intermediate layer 220 may further include a metal-containing compound, such as an organometallic compound, an inorganic material, such as quantum dots, and the like, in addition to various organic materials.

In an embodiment, as shown in FIG. 5A, the intermediate layer 220 may include an emission layer 222 and a first functional layer 221 and a second functional layer 223 respectively disposed under and on the emission layer 222. The first functional layer 221 may include, for example, a hole transport layer (HTL), or an HTL and a hole injection layer (HIL). The second functional layer 223 may be an element disposed on the emission layer 222 and may be optional. The second functional layer 223 may include an electron transport layer (ETL) and/or an electron injection layer (EIL).

In an embodiment, as shown in FIG. 5B, the intermediate layer 220 may be of a tandem type including two or more emitting units EU1, . . . , EUi, . . . , EUk (where k is a natural number equal to or greater than 2) stacked between the first electrode 210 and the second electrode 230 and a charge generation layer CGL disposed between the two adjacent emitting units among the emitting units EU1, . . . , EUi, . . . , EUk. In case that the light-emitting diode LED (e.g., see FIG. 4) has a stacked structure of emitting units EU1, . . . , EUi, . . . , EUk, color purity and light-emitting efficiency may be improved.

Each emitting unit EU1, . . . , EUi, . . . , EUk may include an emission layer and a first functional layer and a second functional layer respectively disposed under and on the emission layer. The charge generation layer CGL may include a negative charge generation layer and a positive charge generation layer. Light-emitting efficiency of a tandem light-emitting diode LED including emission layers may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

Referring back to FIG. 4, the second electrode 230 may be disposed on the intermediate layer 220. The second electrode 230 may include a conductive material having a low work function. For example, the second electrode 230 may include a (semi)transparent layer including at least one of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and an alloy thereof. As another example, the second electrode 230 may further include a layer, such as ITO, IZO, ZnO, or In₂O₃, on a (semi)transparent layer including the above-described material.

Referring to line B-B′ of FIG. 4, the bus line VSL may be disposed above the substrate 100. The bus line VSL and an electrode of the transistor TFT may be formed together by a same process. For example, the bus line VSL and an electrode of the transistor TFT may be formed on a same layer and may include a same material. As an embodiment, FIG. 4 illustrates that the bus line VSL and the gate electrode GE of the transistor TFT are formed together by a same process. The bus line VSL and the gate electrode GE may include a same material, a bottom insulating layer 116 may be disposed under the bus line VSL, and the bottom insulating layer 116 and the gate insulating layer 115 may include a same insulating material. In another embodiment, the bus line VSL and the source electrode SE or the drain electrode DE may be formed together by a same process, and the bus line VSL and the source electrode SE or the drain electrode DE may include a same material.

The bus line VSL may be electrically connected to an auxiliary bus line A-VSL. For example, the bus line VSL may be configured to electrically connect the bus line VSL and the auxiliary bus line A-VSL overlapping the bus line VSL to each other through a connection layer VCNL disposed on the first insulating layer 120. Self-resistance of the bus line VSL may be reduced by electrically connecting the bus line VSL to the auxiliary bus line A-VSL. The auxiliary bus line A-VSL may overlap the bus line VSL. The auxiliary bus line A-VSL and the bottom conductive layer BML may include a same material.

The multi-insulating layer IL may be on the bus line VSL. The multi-insulating layer IL may cover the edge of the bus line VSL and may include an opening IL-OP exposing a portion of the bus line VSL. The multi-insulating layer may include insulating layers, and FIG. 4 illustrates that the multi-insulating layer IL includes the first insulating layer 120 and the second insulating layer 130. The opening IL-OP of the multi-insulating layer IL may pass through a bottom surface of the multi-insulating layer IL from a top surface of the multi-insulating layer IL. In other words, the opening IL-OP of the multi-insulating layer IL may include an opening (hereinafter referred to as a first opening 120OP) of the first insulating layer 120 and an opening (hereinafter referred to as a second opening 130OP) of the second insulating layer 130, the first opening 120OP and the second opening 130OP overlapping each other.

A side surface of the first insulating layer 120 facing/defining the first opening 120OP and a side surface of the second insulating layer 130 facing/defining the second opening 130OP may include a forward-tapered slope. An inclination angle “b” of the side surface of the first insulating layer 120 and an inclination angle “a” of the side surface of the second insulating layer 130 may be substantially the same as each other as shown in FIG. 6A or may be different from each other as shown in FIG. 6B. For example, the inclination angle “b” of the side surface of the first insulating layer 120 may be less than the inclination angle “a” of the side surface of the second insulating layer 130.

A conductive layer CL may be located on the bus line VSL through the opening IL-OP of the multi-insulating layer IL. The conductive layer CL may entirely contact a top surface of the bus line VSL exposed through the opening IL-OP of the multi-insulating layer IL. For example, the conductive layer CL may entirely contact a top surface of the bus line VSL exposed through the first opening 120OP of the first insulating layer 120. An edge portion of the conductive layer CL may be on a side surface of the multi-insulating layer IL and may directly contact the side surface of the multi-insulating layer IL. As an embodiment, FIGS. 4 and 6A illustrate that an edge portion of the conductive layer CL directly contacts the side surface of the first insulating layer 120 of the multi-insulating layer IL and the side surface of the second insulating layer 130, but one or more embodiments are not limited thereto. In another embodiment, an edge portion of the conductive layer CL may contact the side surface of the first insulating layer 120 of the multi-insulating layer IL but may not contact the side surface of the second insulating layer 130. The conductive layer CL may prevent damage to the bus line VSL during a process of manufacturing the display panel DP. The conductive layer CL and the first electrode 210 of the light-emitting diode LED may include a same material.

The third insulating layer 140 may include an opening (hereinafter referred to as a third opening 140OP) overlapping the bus line VSL. The third opening 140OP of the third insulating layer 140 may overlap the opening IL-OP of the multi-insulating layer IL. The third opening 140OP of the third insulating layer 140 may overlap the first opening 120OP of the first insulating layer 120 and the second opening 130OP of the second insulating layer 130.

Referring to FIGS. 4 and 6A, a portion of the third insulating layer 140 surrounding the third opening 140OP may have an overhang structure 140OH. For example, a portion of the third insulating layer 140 surrounding the third opening 140OP may protrude toward the third opening 140OP from a point (or an edge) CP (see FIG. 6A) where the top and side surfaces of the multi-insulating layer IL meet each other, thereby forming the overhang structure 140OH. A horizontal length dl (see FIG. 6A) of the overhang structure 140OH of the third insulating layer 140 may be about 0.1 μm to about 5 μm. In this regard, as shown in FIG. 6A, the horizontal length dl of the overhang structure 140OH may indicate a horizontal length from a point where the bottom and side surfaces of the multi-insulating layer IL meet each other to an edge of the overhang structure 140OH of the third insulating layer 140.

A dummy conductive layer CL-D may be on a portion of the third insulating layer 140 surrounding the third opening 140OP and may be separated from the conductive layer CL. For example, the dummy conductive layer CL-D may overlap a side surface of a portion of the third insulating layer 140 surrounding the third opening 140OP and a portion of a top surface connected to the side surface. For example, the dummy conductive layer CL-D may overlap side and top surfaces of the overhang structure 140OH. The dummy conductive layer CL-D may be formed by a process of forming the conductive layer CL, and the dummy conductive layer CL-D and the conductive layer CL may include a same material.

The fourth insulating layer 150 may be disposed on the third insulating layer 140 and may include an opening (hereinafter referred to as a fourth opening 150OP) overlapping the bus line VSL. The fourth opening 150OP of the fourth insulating layer 150 may overlap the opening IL-OP of the multi-insulating layer IL and the third opening 140OP. In other words, the fourth opening 150OP of the fourth insulating layer 150 may overlap the first opening 120OP of the first insulating layer 120, the second opening 130OP of the second insulating layer 130, and the third opening 140OP of the third insulating layer 140.

A center of the fourth opening 150OP and a center of the third opening 140OP may not be located on a same line. In the schematic cross-sectional view of FIG. 4, an edge of a portion 150A of the fourth insulating layer 150 located on a side (e.g., the left side of FIG. 4) of the fourth opening 150OP may be on a top surface of the third insulating layer 140, and another portion (hereinafter referred to as a bridge portion 150B) of the fourth insulating layer 150 located on an opposite side (e.g., the right side of FIG. 4) of the fourth opening 150OP may extend to a top surface of the conductive layer CL. Accordingly, an edge of the bridge portion 150B may be on the top surface of the conductive layer CL. In other words, the bridge portion 150B of the fourth insulating layer 150 may extend to contact the top surface of the conductive layer CL and may overlap a portion of the overhang structure 140OH of the third insulating layer 140. For example, the overhang structure 140OH of the third insulating layer 140 disposed under the bridge portion 150B of the fourth insulating layer 150 may be covered by the bridge portion 150B of the fourth insulating layer 150. The bridge portion 150B of the fourth insulating layer 150 may have a forward-tapered inclined surface with respect to the top surface of the conductive layer CL.

The intermediate layer 220 of the light-emitting diode LED may be formed by using a mask having an opening greater than or equal to the display area DA. The intermediate layer 220 may also be formed above the bus line VSL, and the intermediate layer 220 may include portions separated by the overhang structure 140OH of the third insulating layer 140 exposed through the fourth opening 150OP. The intermediate layer 220 may include a first portion 220A extending over the conductive layer CL beyond the inclined surface of the bridge portion 150B of the fourth insulating layer 150 and a second portion 220B separated from the first portion 220A and disposed over the overhang structure 140OH.

A depth under the overhang structure 140OH may be defined by a thickness T1 of the multi-insulating layer IL. For example, as shown in FIG. 6A, a depth under the overhang structure 140OH may be equal to the thickness T1 of the multi-insulating layer IL, for example, the sum of a thickness of the first insulating layer 120 and a thickness of the second insulating layer 130. The thickness T1 of the multi-insulating layer IL may be greater than a thickness t2 of the intermediate layer 220. Accordingly, the intermediate layer 220 including layers as described with reference to FIGS. 5A and 5B may be easily separated through the overhang structure 1400H.

The second electrode 230 of the light-emitting diode LED may be formed by using a mask having an opening greater than or equal to the display area DA. The second electrode 230 may also be formed above the bus line VSL, and the second electrode 230 may include portions separated by the overhang structure 140OH of the third insulating layer 140 exposed through the fourth opening 150OP. The second electrode 230 may include a first portion 230A extending over the conductive layer CL beyond the inclined surface of the bridge portion 150B of the fourth insulating layer 150 and a second portion 230B separated from the first portion 230A and disposed over the overhang structure 1400H.

During a process of forming the second electrode 230 of the light-emitting diode LED, a deposition incident angle of a material corresponding to the second electrode 230 may be different from a deposition incident angle of a material corresponding to the intermediate layer 220. Accordingly, an edge 230E1 of the first portion 230A of the second electrode 230 may be closer to an edge of the conductive layer CL than an edge 220E1 of the first portion 220A of the intermediate layer 220. In other words, the first portion 230A of the second electrode 230 may directly contact the top surface of the conductive layer CL beyond the edge 220E1 of the first portion 220A of the intermediate layer 220 and may be electrically connected to the conductive layer CL.

Most of the second electrode 230 may be located over the third insulating layer 140 and the fourth insulating layer 150, and the first portion 230A of the second electrode 230 may extend down along the forward-tapered side surface of the bridge portion 150B of the fourth insulating layer 150, and as shown in FIG. 4, may contact the conductive layer CL under the overhang structure 140OH and be thus electrically connected to the bus line VSL.

Although FIGS. 4 and 6A illustrate that a portion of the second electrode 230, for example, the edge 230E1 of the first portion 230A, is located on an edge portion (or a peripheral portion) of the conductive layer CL located on the side surface of the multi-insulating layer IL, one or more embodiments are not limited thereto. In another embodiment, as shown in FIG. 6C, the edge 230E1 of the first portion 230A, which is a portion of the second electrode 230, may directly contact the side surface of the multi-insulating layer IL beyond the edge of the conductive layer CL. In another embodiment, as shown in FIG. 6D, the edge 230E1 of the first portion 230A, which is a portion of the second electrode 230, may not be on the side surface of the multi-insulating layer IL. For example, as shown in FIG. 6D, the edge 230E1 of the first portion 230A of the second electrode 230 may be on an inner portion of the conductive layer CL overlapping the bus line VSL. The inner portion of the conductive layer CL may indicate a portion surrounded by the edge portion of the conductive layer CL, and may indicate, for example, a portion of the conductive layer CL directly contacting the bus line VSL. The edge portion of the conductive layer CL may be on the side surface of the multi-insulating layer IL, and the inner portion of the conductive layer CL may directly contact the bus line VSL.

Referring to line C-C′ of FIG. 4, a pad PAD may be arranged in the non-display area NDA. The pad PAD of FIG. 4 may correspond to at least one of the pads included in the first and second pad portions PD1 and PD2 described with reference to FIG. 2.

The pad PAD may be disposed on an insulating layer on the substrate 100. For example, FIG. 4 illustrates the pad PAD disposed on the first insulating layer 120. The pad PAD, the source electrode SE, the drain electrode DE, and/or the connection layer VCNL may include a same material.

The edge of the pad PAD may be covered by an insulating layer. As an embodiment, FIG. 4 illustrates that the pad PAD is covered by the second insulating layer 130 and exposed to the outside through a pad opening 130POP of the second insulating layer 130. The pad PAD exposed through the pad opening 130POP may be electrically connected to the first to fourth flexible films CF1 to CF4 as described with reference to FIGS. 1 and 2.

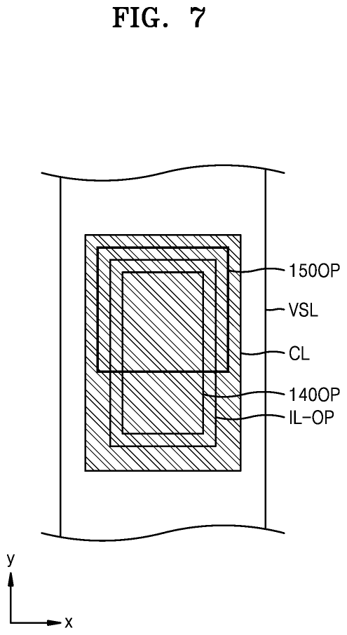

FIG. 7 is a schematic plan view of a structure along line B-B′ shown in FIG. 4.

Referring to FIG. 7, the conductive layer CL may be disposed on the bus line VSL extending in a second direction (e.g., a direction y). The conductive layer CL may have an isolated shape in a plan view and may overlap the bus line VSL.

Referring to line B-B′ of FIG. 4 and FIG. 7, the opening IL-OP of the multi-insulating layer IL may overlap the conductive layer CL and may overlap the bus line VSL. The third opening 140OP of the third insulating layer 140 may overlap the conductive layer CL and may overlap the bus line VSL. The third opening 140OP of the third insulating layer 140 may overlap the opening IL-OP of the multi-insulating layer IL and may have a size (or a width) less than a size (or a width) of the opening IL-OP of the multi-insulating layer IL. For example, a width of the third opening 140OP of the third insulating layer 140 in a first direction (e.g., a direction x) may be less than a width of the opening IL-OP of the multi-insulating layer IL in the first direction (e.g., the direction x). A width of the third opening 140OP of the third insulating layer 140 in the second direction (e.g., the direction y) may be less than a width of the opening IL-OP of the multi-insulating layer IL in the second direction (e.g., the direction y). As shown in FIG. 4, the width of the opening IL-OP of the multi-insulating layer IL may correspond to a horizontal distance between points where a bottom surface of the overhang structure 140OH and the side surface of the multi-insulating layer IL meet each other, and the width of the third opening 140OP of the third insulating layer 140 may correspond to a horizontal distance between edges of the overhang structure 140OH.

The fourth opening 150OP of the fourth insulating layer 150 may overlap the conductive layer CL and may overlap the bus line VSL. The fourth opening 150OP of the fourth insulating layer 150 may overlap a portion of the third opening 140OP of the third insulating layer 140. In other words, while a portion of the third opening 140OP of the third insulating layer 140 overlaps the fourth opening 150OP of the fourth insulating layer 150, another portion thereof may overlap a portion (e.g., the bridge portion 150B) of the fourth insulating layer 150.

The fourth opening 150OP of the fourth insulating layer 150 may overlap a portion of the opening IL-OP of the multi-insulating layer IL. In other words, while a portion of the opening IL-OP of the multi-insulating layer IL overlaps the fourth opening 150OP of the fourth insulating layer 150, another portion thereof may overlap a material portion (e.g., the bridge portion 150B) of the fourth insulating layer 150.

In an embodiment, a width of the fourth opening 150OP of the fourth insulating layer 150 in the first direction (e.g., the direction x) may be greater than a width of the third opening 140OP of the third insulating layer 140 in the first direction (e.g., the direction x) and may be greater than a width of the opening IL-OP of the multi-insulating layer IL in the first direction (e.g., the direction x). A width of the fourth opening 150OP of the fourth insulating layer 150 in the second direction (e.g., the direction y) may be less than a width of the third opening 140OP of the third insulating layer 140 in the second direction (e.g., the direction y) and may be less than a width of the opening IL-OP of the multi-insulating layer IL in the second direction (e.g., the direction y).

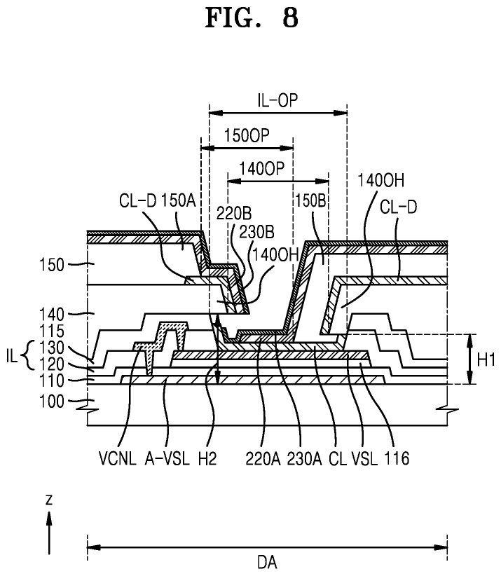

FIG. 8 is a schematic cross-sectional view illustrating a structure on a bus line of a display panel according to another embodiment.

The display panel shown in FIG. 8 may differ at least in the overhang structure 140OH of the third insulating layer 140, other elements may be the same as those described above with reference to FIG. 4, and thus, the differences will be mainly described below. According to the embodiment described with reference to FIG. 4, a vertical distance from the top surface of the substrate 100 to the overhang structure 140OH of the third insulating layer 140 may be constant regardless of the position of the overhang structure 140OH, but one or more embodiments are not limited thereto. In another embodiment, a vertical distance from the top surface of the substrate 100 to a portion of the overhang structure 140OH of the third insulating layer 140 may be different from a vertical distance from the top surface of the substrate 100 to another portion of the overhang structure 140OH of the third insulating layer 140.

For example, as shown in FIG. 8, a first vertical distance H1 from the top surface of the substrate 100 to the overhang structure 140OH overlapping the bridge portion 150B of the fourth insulating layer 150 may be less than a second vertical distance H2 from the top surface of the substrate 100 to the overhang structure 140OH overlapping the fourth opening 150OP of the fourth insulating layer 150.

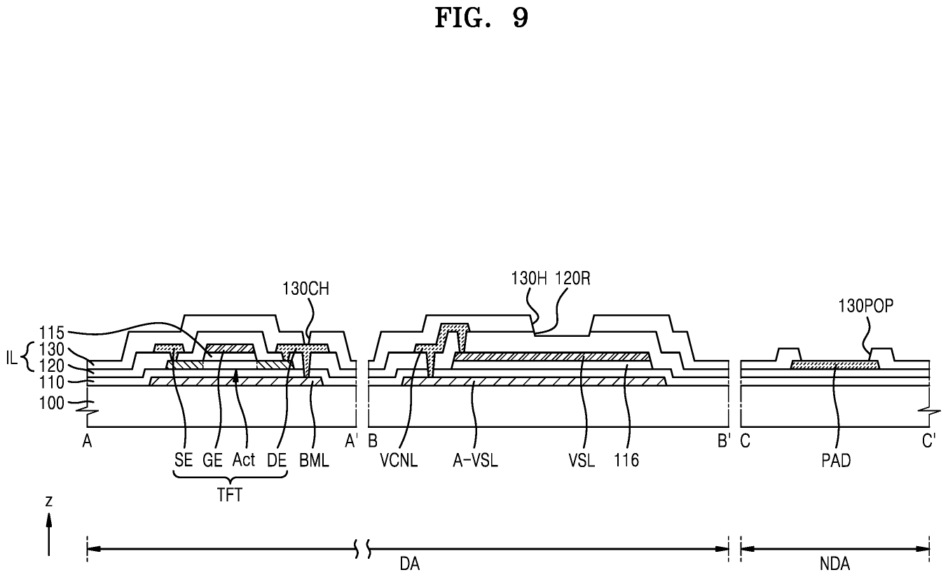

FIGS. 9 to 15 are schematic cross-sectional views of a process of manufacturing a display panel according to an embodiment.

Referring to FIG. 9, the sub-pixel circuit PC may be formed in the display area DA on the substrate 100, and FIG. 9 illustrates the transistor TFT of the sub-pixel circuit PC. The auxiliary bus line A-VSL, the bus line VSL, and the connection layer VCNL may also be formed in the display area DA. The pad PAD may be formed in the non-display area NDA on the substrate 100.

In an embodiment, the auxiliary bus line A-VSL and the bottom conductive layer BML may be formed by a same process. The bus line VSL and at least one of the electrodes (a gate electrode, a source electrode, and a drain electrode) of the transistor TFT may be formed by a same process, and FIG. 9 illustrates that the bus line VSL and the gate electrode GE are formed by a same process, and illustrates that the pad PAD, the connection layer VCNL, and the source electrode SE or the drain electrode DE are formed together by a same process.

The buffer layer 110 may be formed between the bottom conductive layer BML and the semiconductor layer Act and between the auxiliary bus line A-VSL and the bottom conductive layer BML. The buffer layer 110 may extend to the non-display area NDA. The gate insulating layer 115 may be formed between the semiconductor layer Act and the gate electrode GE, and the bottom insulating layer 116 may be formed between the buffer layer 110 and the bus line VSL.

The gate insulating layer 115 and the gate electrode GE may be patterned by a same mask process, and the bottom insulating layer 116 and the bus line VSL may be patterned by a same mask process. In another embodiment, the gate insulating layer 115 and the bottom insulating layer 116 may be integrally connected or extended to each other. The gate insulating layer 115 and the bottom insulating layer 116 integrally connected or extended to each other may entirely cover a top surface of the substrate 100 as the buffer layer 110 does, and may extend to the non-display area NDA.

The first insulating layer 120 may be formed between the gate electrode GE and the source electrode SE and/or between the gate electrode GE and the drain electrode DE and may be formed between the bus line VSL and the connection layer VCNL. For example, the first insulating layer 120 may include an inorganic insulating material.

The second insulating layer 130 may be formed on the source electrode SE and/or the drain electrode DE, the connection layer VCNL, and the pad PAD. For example, the second insulating layer 130 may include an inorganic insulating material.

The second insulating layer 130 may include a contact hole 130CH exposing the transistor TFT. During a process of forming the contact hole 130CH of the second insulating layer 130 (e.g., a dry etching process), a hole 130H of the second insulating layer 130 and a recess 120R of the first insulating layer 120 overlapping a portion of the bus line VSL and the pad opening 130POP overlapping the pad PAD may be formed.

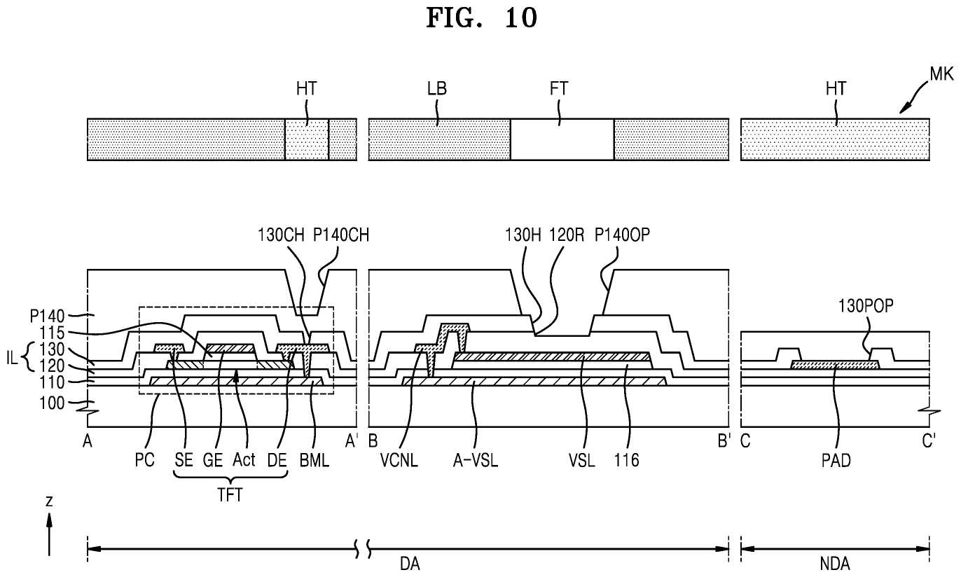

Referring to FIG. 10, a preliminary-third insulating layer P140 may be formed. The preliminary-third insulating layer P140 may include an organic insulating material. The preliminary-third insulating layer P140 may be exposed by using an exposure mask MK including a light-blocking area LB, a half-tone area HT, and a full-tone area FT and may be developed. The preliminary-third insulating layer P140 formed by the above-described process may include a preliminary-contact hole P140CH overlapping the contact hole 130CH of the second insulating layer 130 and a preliminary-opening P140OP overlapping the hole 130H of the second insulating layer 130 and the recess 120R of the first insulating layer 120.

The preliminary-opening P140OP corresponding to the full-tone area FT of the exposure mask MK may have the shape of a through hole that penetrates top and bottom surfaces of the preliminary-third insulating layer P140. The preliminary-contact hole P140CH corresponding to the half-tone area HT of the exposure mask MK may have the shape of a blind hole that does not penetrate the bottom surface of the preliminary-third insulating layer P140. A thickness of a portion of the preliminary-third insulating layer P140 corresponding to the half-tone area HT of the exposure mask MK and arranged in the non-display area NDA may be less than a thickness of another portion of the preliminary-third insulating layer P140 corresponding to the light-blocking area LB and arranged in the display area DA (for example, a portion around the preliminary-contact hole P140CH and/or the preliminary-opening P140OP).

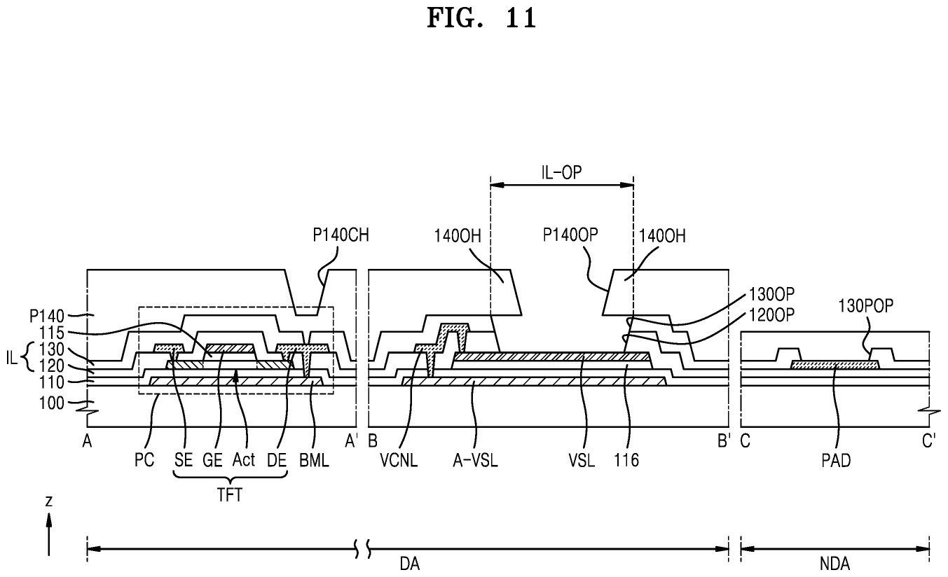

Referring to FIG. 11, the overhang structure 140OH may be formed by removing a portion of the multi-insulating layer IL through the preliminary-opening P140OP of the preliminary-third insulating layer P140. For example, the first opening 120OP of the first insulating layer 120 and the second opening 130OP of the second insulating layer 130 may be formed by removing a portion of the first insulating layer 120 and a portion of the second insulating layer 130 through the preliminary-opening P140OP of the preliminary-third insulating layer P140. The first opening 120OP and the second opening 130OP overlapping each other may correspond to the opening IL-OP of the multi-insulating layer IL.

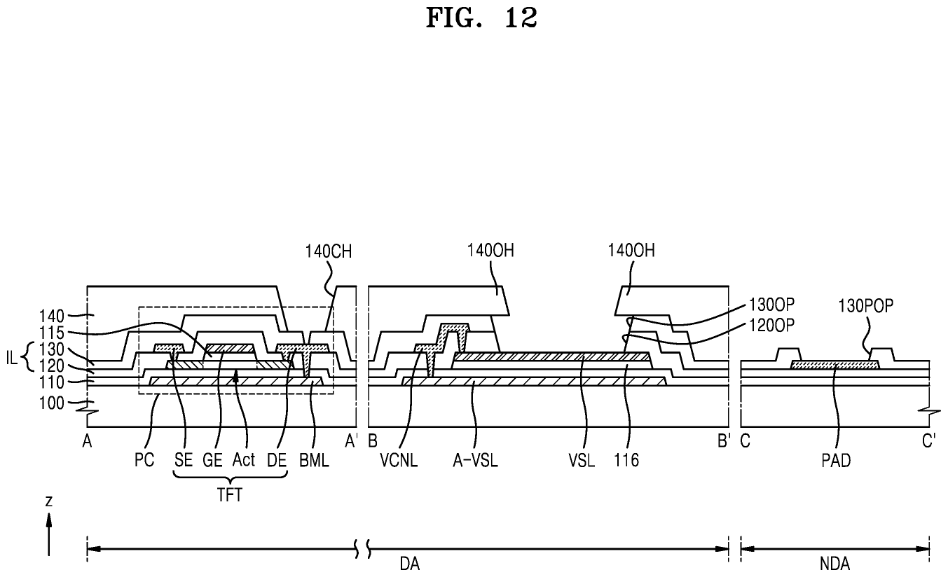

The third insulating layer 140 may be formed by ashing the preliminary-third insulating layer P140. By the ashing process, a portion of the preliminary-third insulating layer P140 arranged in the non-display area NDA may all be removed, and a contact hole 140CH exposing an electrode of the transistor TFT (e.g., the drain electrode DE of the transistor TFT) may be formed. Although the third insulating layer 140 is not formed in the non-display area NDA by the ashing process as shown in FIG. 12, the pad PAD may be covered and protected by a portion of the preliminary-third insulating layer P140 present in the non-display area NDA during the process described with reference to FIG. 11, and thus, the pad PAD may be prevented from being damaged by an etching process for forming the first opening 120OP of the first insulating layer 120 and the second opening 130OP of the second insulating layer 130.

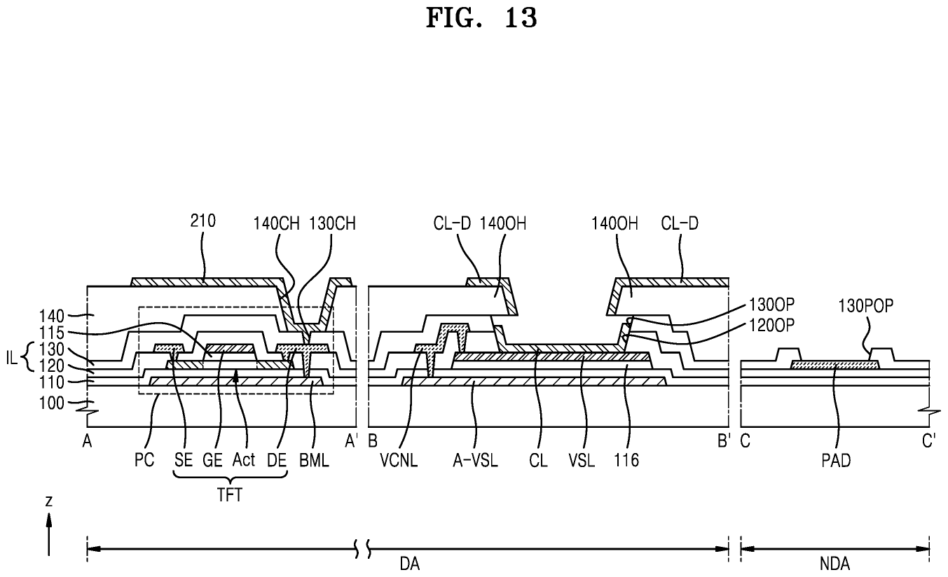

Referring to FIG. 13, the first electrode 210 of a light-emitting diode may be formed on the third insulating layer 140. The first electrode 210 may be electrically connected to the sub-pixel circuit PC, for example, the transistor TFT, through the contact hole 140CH of the third insulating layer 140 and the contact hole 130CH of the second insulating layer 130.

The conductive layer CL may be formed on the bus line VSL. The conductive layer CL and the first electrode 210 may include a same material and may be formed together by a same process. Due to the overhang structure 140OH above the bus line VSL, a material for forming the conductive layer CL may also be present on the overhang structure 140OH. FIG. 13 illustrates that the dummy conductive layer CL-D is formed on the overhang structure 140OH. The dummy conductive layer CL-D may be separated from the conductive layer CL.

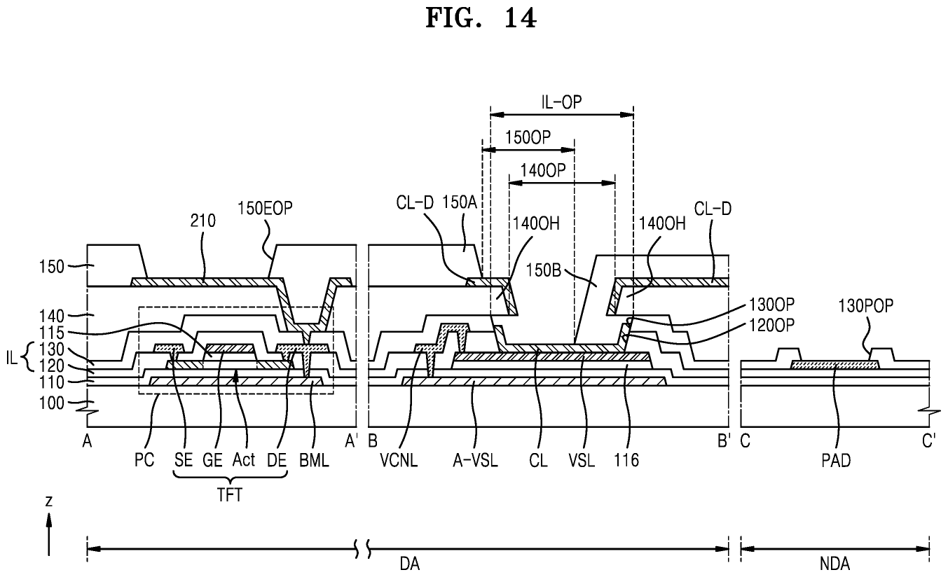

As shown in FIG. 14, the fourth insulating layer 150 may be formed. The fourth insulating layer 150 may include an emission opening 150EOP overlapping the first electrode 210. The fourth insulating layer 150 may include the fourth opening 150OP overlapping the conductive layer CL.

The fourth opening 150OP of the fourth insulating layer 150 may overlap the opening IL-OP of the multi-insulating layer IL and the third opening 140OP. In other words, the fourth opening 150OP of the fourth insulating layer 150 may overlap the first opening 120OP of the first insulating layer 120, the second opening 130OP of the second insulating layer 130, and the third opening 140OP of the third insulating layer 140.

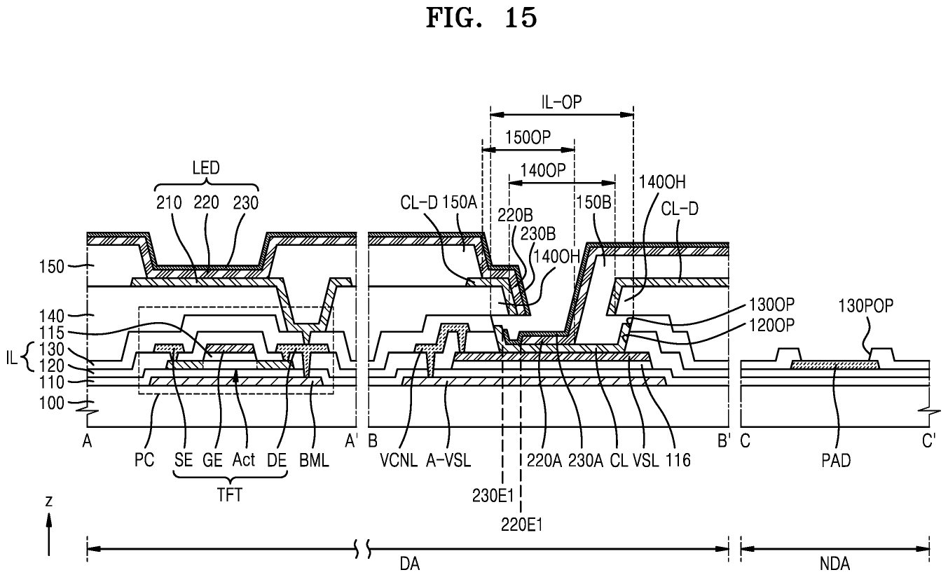

As described above with reference to FIGS. 4 and 7, a center of the fourth opening 150OP and a center of the third opening 140OP may not be located on a same line, and as shown in FIG. 14, a portion of the fourth insulating layer 150 may extend over the conductive layer CL while covering (or overlapping) the overhang structure 140OH, thereby forming the bridge portion 150B. The bridge portion 150B may have a forward-tapered slope such that a portion of the second electrode 230 to be formed by a process described below with reference to FIG. 15 directly contacts the conductive layer CL without being separated by the overhang structure 140OH.

Referring to FIG. 15, the intermediate layer 220 and the second electrode 230 may be formed on the fourth insulating layer 150.

The intermediate layer 220 may be formed by using a mask having an opening as large as or larger than the display area DA, and accordingly, the intermediate layer 220 may also be formed on the conductive layer CL and the bus line VSL. The intermediate layer 220 may be separated by the overhang structure 140OH of the third insulating layer 140 exposed through the fourth opening 150OP. For example, the intermediate layer 220 may include the first portion 220A located over an inclined surface of the bridge portion 150B of the fourth insulating layer 150 and the second portion 220B separated from the first portion 220A and disposed over the overhang structure 1400H.

The second electrode 230 may be formed by using a mask having an opening as large as or larger than the display area DA, and accordingly, the second electrode 230 may also be formed on the conductive layer CL and the bus line VSL. The second electrode 230 may be separated by the overhang structure 140OH of the third insulating layer 140 exposed through the fourth opening 150OP. The second electrode 230 may include the first portion 230A disposed over the inclined surface of the bridge portion 150B of the fourth insulating layer 150 and the second portion 230B separated from the first portion 230A and disposed over the overhang structure 140OH.

A deposition incident angle of a material corresponding to the second electrode 230 may be different from a deposition incident angle of a material corresponding to the intermediate layer 220, and accordingly, the edge 230E1 of the first portion 230A of the second electrode 230 may further extend over the conductive layer CL than the edge 220E1 of the first portion 220A of the intermediate layer 220 to directly contact the conductive layer CL.

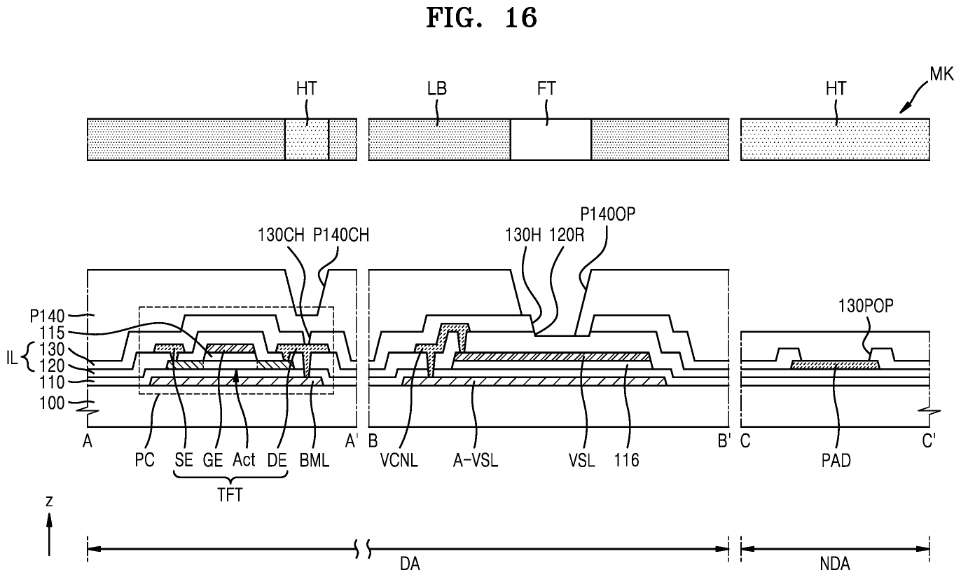

FIGS. 16 to 18 are schematic cross-sectional views illustrating part of a process of manufacturing a display panel according to another embodiment and may correspond to modified embodiments of FIGS. 10 to 12, respectively.

According to the process described with reference to FIG. 10, a bottom surface of the peripheral portion of the preliminary-opening P140OP of the preliminary-third insulating layer P140 may directly contact a top surface of the second insulating layer 130. In a plan view (or when viewed in a direction vertical to a top surface of the substrate 100), a center of the preliminary-opening P140OP of the preliminary-third insulating layer P140 and centers of the hole 130H of the second insulating layer 130 and the recess 120R of the first insulating layer 120 may be located at substantially a same position. Accordingly, as shown in FIG. 11, a vertical distance from the top surface of the substrate 100 to the overhang structure 140OH may be constant regardless of the position.

In another embodiment, as shown in FIG. 16, a portion of the bottom surface of the peripheral portion of the preliminary-opening P140OP of the preliminary-third insulating layer P140 may directly contact the top surface of the second insulating layer 130, whereas another portion thereof may directly contact the first insulating layer 120 corresponding to the recess 120R. In other words, in a plan view, a center of the preliminary-opening P140OP may be apart from centers of the hole 130H of the second insulating layer 130 and the recess 120R of the first insulating layer 120 by a certain distance.

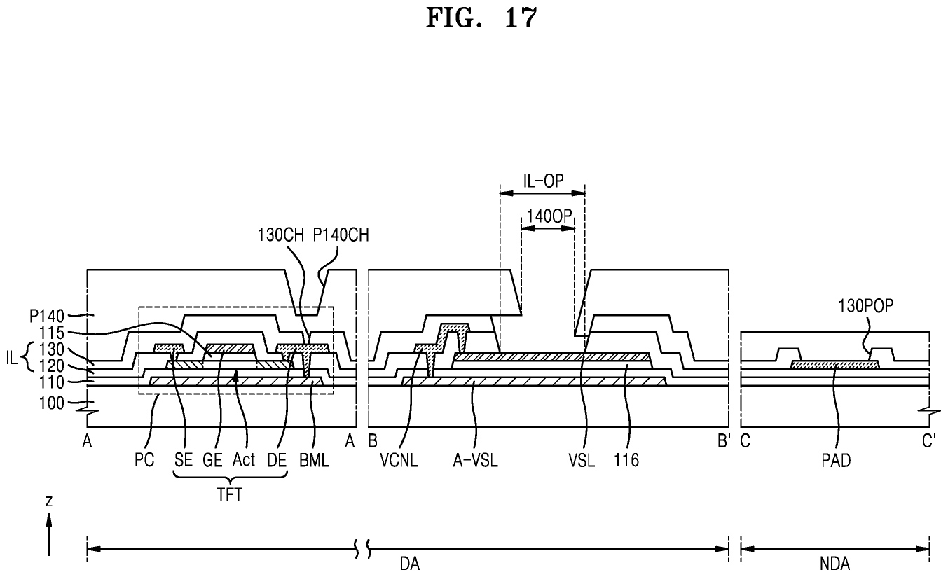

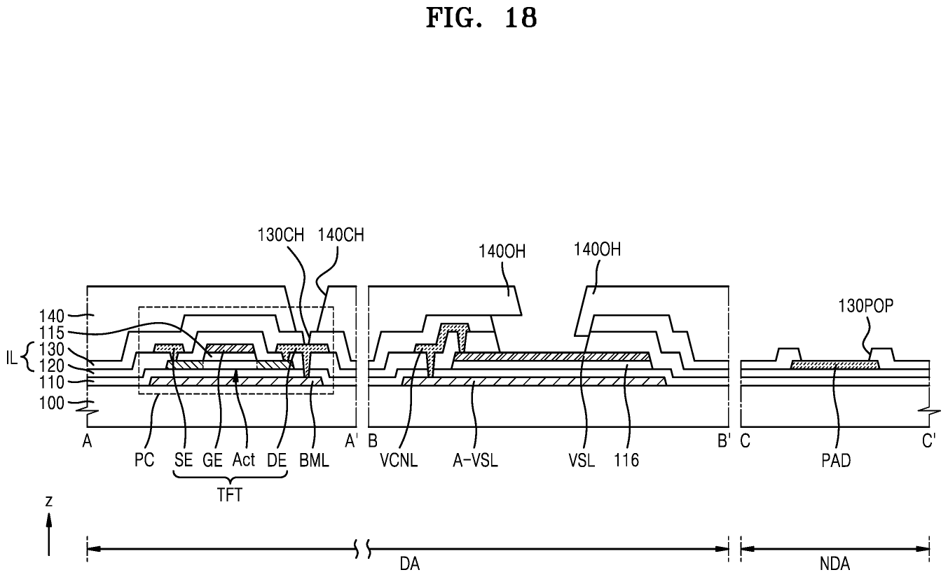

As shown in FIG. 17, the overhang structure 140OH (e.g., see FIG. 18) may be formed by removing a portion of the multi-insulating layer IL through the preliminary-opening P140OP of the preliminary-third insulating layer P140. For example, the opening IL-OP of the multi-insulating layer IL may be formed by removing a portion of the first insulating layer 120 and a portion of the second insulating layer 130 or removing a portion of the first insulating layer 120 through the preliminary-opening P140OP of the preliminary-third insulating layer P140.

The third insulating layer 140 may be formed as shown in FIG. 18 by ashing the preliminary-third insulating layer P140 (e.g., see FIG. 17). Subsequent processes may be the same as those described with reference to FIGS. 13 and 14, and a display panel having the overhang structure 140OH shown in FIG. 18 may be the same as that described above with reference to FIG. 8.

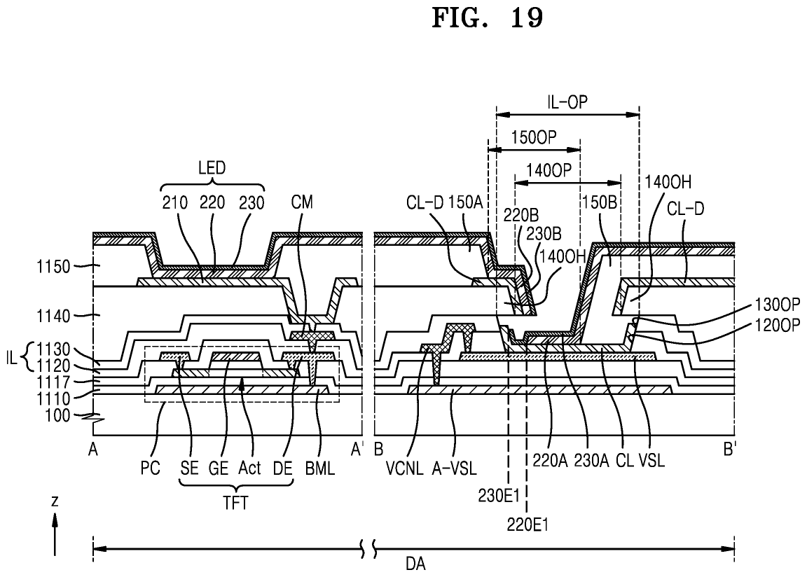

FIG. 19 is a schematic cross-sectional view illustrating a display area of a display panel according to another embodiment.

In the display panel shown in FIG. 15, the first electrode 210 of the light-emitting diode LED may be directly connected to the transistor TFT through a contact hole of the third insulating layer 140, but one or more embodiments are not limited thereto. In another embodiment, as shown in FIG. 19, a conductor CM may be further disposed between the first electrode 210 and the transistor TFT, and the first electrode 210 and the transistor TFT may be electrically connected to each other through the conductor CM. The conductor CM may be disposed between a second insulating layer 1130 and a first insulating layer 1120, may include a conductive material including molybdenum (Mo), aluminum (Al), copper (Cu), titanium (Ti), etc., and may have a multi-layer or single-layer structure including the above-described material.

An interlayer insulating layer 1117 may be disposed between the gate electrode GE and the source electrode SE of the transistor TFT, between the gate electrode GE and the drain electrode DE, and/or between the bus line VSL and the auxiliary bus line A-VSL. The interlayer insulating layer 1117 may include an inorganic insulating material. A buffer layer 1110 may be disposed between the bottom conductive layer BML and the semiconductor layer Act of the transistor TFT, and a first insulating layer 1120 may be disposed on the source electrode SE and/or the drain electrode DE and under the second insulating layer 1130. The first insulating layer 1120, the second insulating layer 1130, the third insulating layer 1140, and a fourth insulating layer 1150 and the first insulating layer 120, the second insulating layer 130, the third insulating layer 140, and the fourth insulating layer 150 described above with reference to FIG. 4 may include same materials, respectively.

The bus line VSL may be disposed on the interlayer insulating layer 1117, and the bus line VSL and the source electrode SE and/or the drain electrode DE may include a same material. The bus line VSL may be electrically connected to the auxiliary bus line A-VSL by the connection layer VCNL, and the connection layer VCNL and the conductor CM may include a same material.

A structure on the bus line VSL, for example, an overhang structure 140OH on the conductive layer CL or an electrical connection structure between the second electrode 230 and the conductive layer CL, may be the same as that described above with reference to FIGS. 4 to 8.

According to one or more embodiments, a voltage drop of a second electrode of a light-emitting diode may be prevented by using openings of insulating layers on a bus line, and a pad may be prevented from being damaged during a process for electrical connection between the bus line and the second electrode of the light-emitting diode. However, such an effect is an example, and one or more embodiments are not limited by the above effect.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a transistor;
a light-emitting diode comprising:
a first electrode electrically connected to the transistor;
a second electrode on the first electrode; and
an intermediate layer between the first electrode and the second electrode;
a bus line adjacent to the light-emitting diode;
a first insulating layer arranged on the bus line;
a second insulating layer arranged on the first insulating layer;
a conductive layer electrically connected to the bus line through a first opening defined in the first insulating layer and a second opening defined in the second insulating layer;
a third insulating layer arranged on the second insulating layer and comprising a third opening overlapping the first opening and the second opening in a plan view; and
a fourth insulating layer arranged on the third insulating layer and comprising a fourth opening overlapping the conductive layer in a plan view,
wherein a portion of the second electrode of the light-emitting diode is in contact with the conductive layer through the third opening and the fourth opening.

2. The display apparatus of claim 1, wherein the conductive layer is in contact with an entire top surface of the bus line which is exposed through the first opening of the first insulating layer.

3. The display apparatus of claim 2, wherein an edge portion of the conductive layer is in direct contact with a side surface of the first insulating layer defining the first opening.

4. The display apparatus of claim 1, wherein a portion of the third insulating layer surrounding the third opening comprises an overhang structure protruding toward the third opening from an edge where top and side surfaces of the second insulating layer meet each other.

5. The display apparatus of claim 4, further comprising:
a dummy conductive layer located on the overhang structure of the third insulating layer and separated from the conductive layer,
wherein the dummy conductive layer and the conductive layer comprise a same material.

6. The display apparatus of claim 4, wherein a portion of the fourth insulating layer overlaps a portion of the overhang structure of the third insulating layer in a plan view and has a forward-tapered inclined surface with respect to a top surface of the conductive layer.

7. The display apparatus of claim 6, wherein the intermediate layer comprises:
a first portion arranged on the forward-tapered inclined surface of the fourth insulating layer and the top surface of the conductive layer; and
a second portion separated from the first portion and located over the overhang structure,
wherein the portion of the second electrode of the light-emitting diode is in direct contact with the conductive layer beyond an edge of the first portion of the intermediate layer.

8. The display apparatus of claim 1, wherein the conductive layer and the first electrode of the light-emitting diode comprise a same material.

9. The display apparatus of claim 1, wherein
the transistor comprises:
a semiconductor layer;
a gate electrode overlapping a channel region of the semiconductor layer in a plan view; and
an electrode electrically connected to one selected from among regions arranged on sides of the channel region of the semiconductor layer, and
the bus line and the gate electrode or the electrode comprise a same material.

10. The display apparatus of claim 1, wherein the first insulating layer and the second insulating layer comprise inorganic insulating materials different from each other.

11. The display apparatus of claim 10, wherein an inclination angle of a side surface of the first insulating layer defining the first opening is different from an inclination angle of a side surface of the second insulating layer defining the second opening.

12. A display apparatus comprising:
a display area and a non-display area outside the display area;
a bus line arranged in the display area;
a multi-insulating layer comprising a first insulating layer and a second insulating layer and having an opening overlapping the bus line in a plan view;
a conductive layer in direct contact with the bus line through the opening of the multi-insulating layer;
a third insulating layer arranged on the multi-insulating layer and comprising an overhang structure protruding from an edge where top and side surfaces of the multi-insulating layer meet each other;
a fourth insulating layer arranged on the third insulating layer; and
a light-emitting diode arranged in the display area and comprising:
a first electrode;
a second electrode on the first electrode; and
an intermediate layer between the first electrode and the second electrode,
wherein the second electrode of the light-emitting diode is electrically connected to the conductive layer through an opening of the third insulating layer and an opening of the fourth insulating layer each overlapping the opening of the multi-insulating layer in a plan view.

13. The display apparatus of claim 12, wherein an edge of the conductive layer is on the side surface of the multi-insulating layer.

14. The display apparatus of claim 12, wherein each of the first insulating layer and the second insulating layer comprises an inorganic insulating material.

15. The display apparatus of claim 14, wherein the inorganic insulating material of the first insulating layer is different from the inorganic insulating material of the second insulating layer.

16. The display apparatus of claim 12, further comprising:
a dummy conductive layer located on the overhang structure of the third insulating layer and separated from the conductive layer,
wherein the dummy conductive layer and the conductive layer comprise a same material.

17. The display apparatus of claim 12, wherein a portion of the fourth insulating layer overlaps a portion of the overhang structure of the third insulating layer in a plan view and has a forward-tapered inclined surface with respect to a top surface of the conductive layer.

18. The display apparatus of claim 17, wherein the intermediate layer comprises:
a first portion arranged on the forward-tapered inclined surface of the fourth insulating layer and the top surface of the conductive layer; and
a second portion separated from the first portion and located over the overhang structure,
wherein a portion of the second electrode of the light-emitting diode is in direct contact with the conductive layer beyond an edge of the first portion of the intermediate layer.

19. The display apparatus of claim 12, wherein the conductive layer and the first electrode of the light-emitting diode comprise a same material.

20. The display apparatus of claim 12, further comprising:
a transistor arranged in the display area and electrically connected to the first electrode of the light-emitting diode, wherein
the transistor comprises:
a semiconductor layer;
a gate electrode overlapping a channel region of the semiconductor layer in a plan view; and
an electrode electrically connected to one region selected from among regions arranged on sides of the channel region of the transistor, and
the bus line and the gate electrode or the electrode comprise a same material.
